(19) United States
(12) Patent Application Publication
(10) Pub. No.: US 2025/0140736 A1
(43) Pub. Date: May 1, 2025

(54) POSITIONING EQUIPMENT, BONDING EQUIPMENT, POSITIONING METHOD AND BONDING METHOD

(71) Applicant: Panasonic Intellectual Property Management Co., Ltd., Osaka (JP)

(72) Inventors: RYO FUJITA, Hyogo (JP); MASARU HAMAHIRA, Fukuoka (JP)

(21) Appl. No.: 19/004,085

(22) Filed: Dec. 27, 2024

Related U.S. Application Data
(63) Continuation of application No. PCT/JP2023/014747, filed on Apr. 11, 2023.

(30) Foreign Application Priority Data
Jul. 11, 2022 (JP) 2022-111045

(51) Int. Cl. H01L 23/00; H01L 21/66; H04N 23/52; H04N 23/55; H04N 23/56

(52) U.S. Cl. CPC H01L 24/74; H01L 22/26; H01L 24/80; H04N 23/52; H04N 23/55; H04N 23/56; H01L 2224/74; H01L 2224/8013; H01L 2924/40

(57) ABSTRACT

A positioning equipment includes a camera, a lens disposed in an imaging direction of the camera, a light synthesis unit, and an arithmetic equipment. The light synthesis unit is disposed between a bonding head and a stage when a first component and a second component are positioned, synthesizes light incident from the bonding head side and light incident from the stage side, and reflects the synthesized light to the lens side. The camera images a camera image based on light incident via the lens. The arithmetic equipment obtains a position correction amount between the first component and the second component based on the camera image.

### TECHNICAL FIELD

The present disclosure relates to, for example, a positioning equipment used when positioning of an electronic component or the like is performed, a bonding equipment, a positioning method, and a bonding method.

### BACKGROUND ART

Conventionally, when an electronic component or the like is manufactured, a position of a component such as a substrate or a chip component is grasped using a camera, and positioning of each component is performed. At that time, movement for correcting positional deviation of each component is performed based on a positional deviation amount recognized by the camera, and a movement error can be reduced by minimizing the movement amount of a bonding head or a stage after recognition correction.

For example, in PTL 1, an optical system is used in which components are arranged immediately above a bonding position of a substrate, and a chip back surface serving as a joint surface to each other and a positioning mark on a substrate surface can be recognized. In particular, in PTL 1, an optical system for an upper field of view for imaging a positioning mark on the chip back surface and an optical system for a lower field of view for imaging a positioning mark on a substrate surface are separately configured, therefore, an optical axis of the upper field of view and an optical axis of the lower field of view after reflection of a prism become coaxial, and the upper field of view and the lower field of view can be coaxially imaged. With such structure, if the horizontal positions of the chip and the substrate are matched from the information imaged by the optical system, the chip can be mounted on the substrate only by lowering the operation of the bonding head, therefore, an error due to equipment movement can be minimized and highly accurate bonding can be performed.

### CITATION LIST

### Patent Literature

PTL 1: Japanese Patent No. 4642565

### SUMMARY OF THE INVENTION

However, in a case where ultra-high accuracy positioning of 10 μm or less is performed, only slight thermal expansion of some components or a plurality of components such as a prism, a mirror, and a camera constituting an optical system for chip recognition and an optical system for substrate recognition causes a deviation in an optical path. Thus, coaxiality of the optical path for chip recognition and the optical path for substrate recognition is broken, and positioning accuracy deteriorates.

An object of the present disclosure is to provide a positioning equipment, a bonding equipment, a positioning method, and a bonding method that can deter an accuracy decrease in positioning.

In order to achieve the above object, a positioning equipment according to an exemplary embodiment of the present disclosure is a positioning equipment that positions a first component retained by a bonding head and a second component placed on a stage when the first component is mounted on the second component. The positioning equipment includes a camera, a lens disposed in an optical axis direction of the camera, an optical element, and an arithmetic equipment. The optical element is disposed between the bonding head and the stage when the first component and the second component are positioned, synthesizes light incident from the bonding head side and light incident from the stage side, and reflects the synthesized light to the lens side, the camera images a camera image based on light incident via the lens, and the arithmetic equipment obtains a position correction amount between the first component and the second component based on the camera image.

According to the present disclosure, it is possible to deter the accuracy decrease in positioning.

### BRIEF DESCRIPTION OF THE DRAWINGS

FIG. 1 is a side view of a positioning equipment according to a first exemplary embodiment.

FIG. 2 is a flowchart for explaining an operation of the positioning equipment according to the first exemplary embodiment.

FIG. 3 is an image example of a camera image.

FIG. 4 is a side view of a positioning equipment according to a second exemplary embodiment.

FIG. 5 is a side view of a positioning equipment according to a third exemplary embodiment.

FIG. 6 is a side view of a positioning equipment according to a fourth exemplary embodiment.

FIG. 7 is a side view of a positioning equipment according to a fifth exemplary embodiment.

FIG. 8 is a side view of a positioning equipment according to a sixth exemplary embodiment.

FIG. 9 is a side view of a positioning equipment according to a seventh exemplary embodiment.

FIG. 10 is a side view of a positioning equipment according to an eighth exemplary embodiment.

FIG. 11 is a side view of a positioning equipment according to a ninth exemplary embodiment.

### DESCRIPTION OF EMBODIMENT

Hereinafter, exemplary embodiments of the present invention will be described in detail with reference to the drawings. The following description of preferable exemplary embodiments is merely substantially an example, and is not intended to limit the present invention and applications or uses of the present invention.

### First Exemplary Embodiment

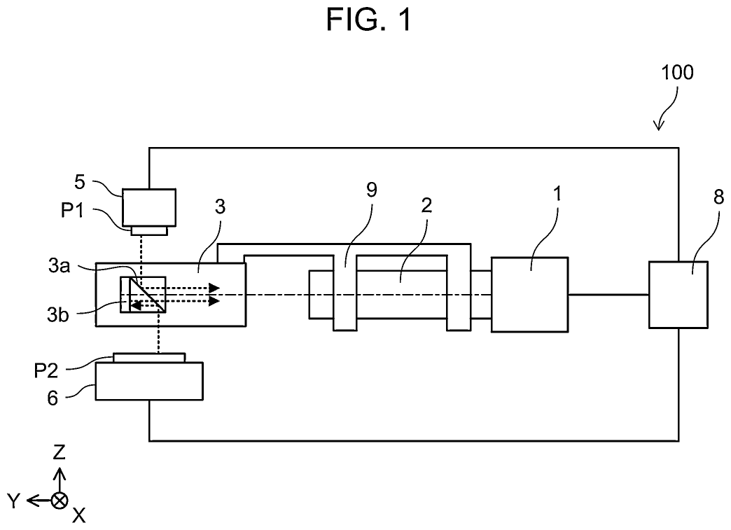

FIG. 1 illustrates a side view of a positioning equipment according to a first exemplary embodiment. Note that, in the following description, an imaging direction of camera 1 (an optical axis direction of lens 2) is a Y direction, an up-down direction is a Z direction, and a direction perpendicular to the Y direction and the Z direction is an X direction.

As illustrated in FIG. 1, positioning equipment 100 according to the first exemplary embodiment includes camera 1, lens 2, light synthesis unit 3 (optical element), and arithmetic equipment 8. An example of arithmetic equipment 8 is a computer including a processor. In addition, as illustrated in FIG. 1, first component P1 is retained by bonding head 5, and second component P2 is placed on stage 6. Note that, positioning equipment 100, bonding head 5, and stage 6 correspond to a bonding equipment.

Camera 1 images, via lens 2 and light synthesis unit 3, first component P1 retained by bonding head 5 and second component P2 placed on stage 6 (details will be described later). Camera 1 outputs an imaged camera image to arithmetic equipment 8.

Lens 2 is attached such that an optical axis coincides with the imaging direction of camera 1. Lens 2 is desirably a telecentric optical system in which a change in position is small even though an in-focus position is slightly deviated, but this case is not applied in a case where workpiece conveyance accuracy to the in-focus position is high.

Light synthesis unit 3 is disposed on the optical axis of lens 2 (imaging direction of camera 1).

Light synthesis unit 3 includes half mirror 3a and mirror 3b.

As illustrated in FIG. 1, half mirror 3a reflects light incident from bonding head 5 in the optical axis direction of lens 2. In addition, half mirror 3a reflects light incident from stage 6 to mirror 3b. Mirror 3b reflects light incident from half mirror 3a in the optical axis direction of lens 2. That is, half mirror 3a and mirror 3b synthesize the light incident from bonding head 5 and the light incident from stage 6, and reflect the synthesized light toward lens 2. For example, half mirror 3a is disposed to have an inclination of 45° with respect to an XZ plane. Note that, half mirror 3a may reflect the light incident from bonding head 5 to mirror 3b and may reflect the light incident from stage 6 in the optical axis direction of lens 2. In addition, half mirror 3a is not necessarily a cube type, and may be a flat plate type.

As illustrated in FIG. 1, lens 2 and light synthesis unit 3 are retained by optical unit base 9. Note that, a position adjustment mechanism such as focusing may be given between lens 2 and optical unit base 9. In addition, a fine position adjustment mechanism may be given between light synthesis unit 3 and optical unit base 9. In addition, in the present exemplary embodiment, lens 2 and light synthesis unit 3 are fixed by identical optical unit base 9, but optical unit base 9 may be installed for each of lens 2 and light synthesis unit 3.

As described above, first component P1 is retained by bonding head 5, and second component P2 is placed on stage 6. For example, first component P1 is a chip component, and second component P2 is a substrate. The first component and the second component are parts of a finished product such as an electronic component. First component P1 and second component P2 are picked up by, for example, a supply head (not illustrated), and then retained and placed on bonding head 5 and stage 6, respectively.

Note that, although not illustrated, positions of bonding head 5 and stage 6 can be changed by a moving mechanism. Specifically, relative positions of bonding head 5 and stage 6 can be changed in an XY direction that is a horizontal direction, a Z direction that is a vertical direction, and a θ direction that is a rotation direction with respect to the Z axis, respectively. During a bonding operation, in the case of bonding head 5 and stage 6, bonding head 5 moves in a −Z direction toward stage 6. In this case, an optical system (camera 1, lens 2, light synthesis unit 3, and the like) moves (advances and retracts) in the Y direction or the X direction such that bonding head 5 does not collide with light synthesis unit 3. At this time, the entire optical system may be moved, or only light synthesis unit 3 may retract.

### (Regarding Operation of Positioning Equipment)

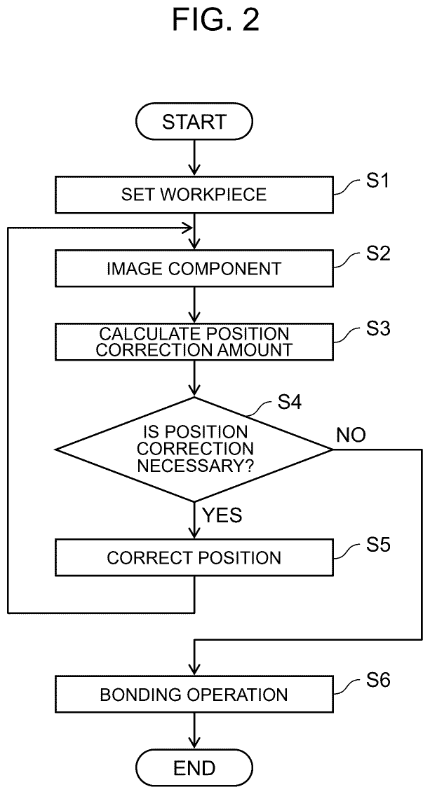

FIG. 2 is a flowchart for explaining an operation of the positioning equipment according to the first exemplary embodiment.

First, the workpiece is set in the positioning equipment (step S1). Specifically, by a supply head not illustrated, first component P1 is retained by bonding head 5, and second component P2 is placed on stage 6. At this time, a surface of first component P1 and a surface of second component P2 are each given an alignment point. First component P1 and second component P2 are retained and placed on bonding head 5 and stage 6 such that these alignment points face each other. Note that, this alignment point is, for example, a mark or an electrode in a case of a flip chip bonder. In addition, in the case of the flip chip bonder, first component P1 is picked up by the supply head, and then flipped upside down and retained by bonding head 5. On the other hand, in the case of a die bonder type, after picked up by the supply head, first component P1 is retained by bonding head 5 without being flipped upside down. At that time, the first component is often placed once on a dedicated stage (not illustrated) or the like, but a path until the first component is retained by bonding head 5 is not limited. Note that, in the die bonder type, bonding head 5 may directly pick up first component P1 from a wafer without using the supply head.

Camera 1 images first component P1 and second component P2 (step S2). Specifically, camera 1, lens 2, and light synthesis unit 3 are moved, and light synthesis unit 3 is disposed between first component P1 (bonding head 5) and second component P2 (stage 6). Then, camera 1 outputs, to arithmetic equipment 8, camera images A in which first component P1 and second component P2 are imaged.

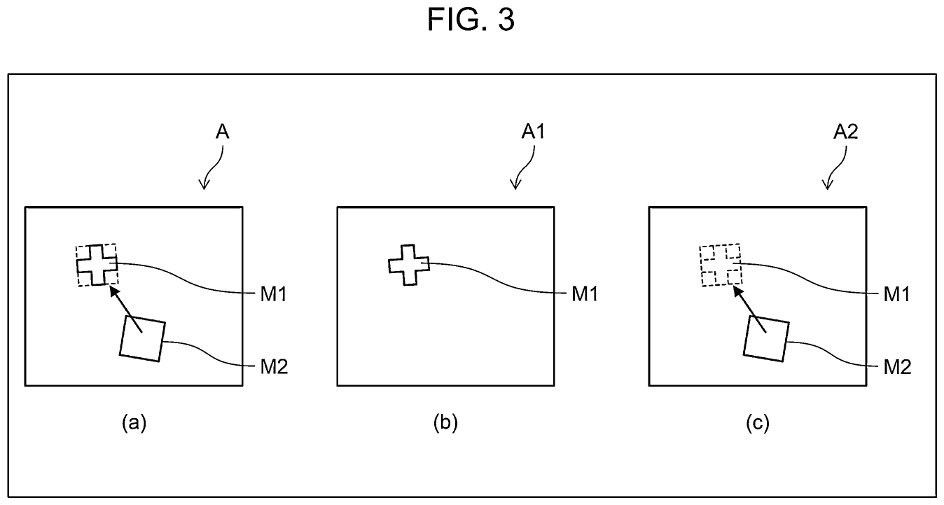

Arithmetic equipment 8 obtains a relative position between first component P1 and second component P2 based on camera images A, and calculates a position correction amount between first component P1 and second component P2 (step S3). Specifically, a mark included in camera images A and used for positioning is detected. Part (a) of FIG. 3 is an image example of the camera image according to the first exemplary embodiment. In part (a) of FIG. 3, marks M1, M2 are marks used for positioning first component P1 and second component P2, respectively. Overlapping positions of marks M1, M2 are reference positions of first component P1 and second component P2. That is, a distance between marks M1, M2 is the position correction amount between first component P1 and second component P2. Note that, in FIG. 3, mark M1 has a cross shape, and mark M2 has a square shape. However, the shapes of marks M1, M2 can be voluntarily set.

Arithmetic equipment 8 determines whether or not position correction is necessary based on the calculated position correction amount (step S4). In a case where the position correction amount is greater than or equal to a predetermined value, arithmetic equipment 8 determines that the position correction is necessary (Yes in step S4), and corrects (moves) positions of first component P1 and second component P2 based on the position correction amount calculated in step S3 (step S5). Thereafter, the processing returns to step S2.

On the other hand, in a case where the position correction amount is less than or equal to the predetermined value, arithmetic equipment 8 determines that the position correction is unnecessary (NO in step S4) and performs a bonding operation (step S6). Specifically, bonding head 5 is moved in the Z direction toward stage 6, and first component P1 is placed on second component P2.

As described above, positioning equipment 100 according to the first exemplary embodiment includes camera 1, lens 2 disposed in the imaging direction of camera 1, light synthesis unit 3 (optical element), and arithmetic equipment 8. When first component P1 and second component P2 are positioned, light synthesis unit 3 is disposed between bonding head 5 and stage 6, synthesizes light incident from bonding head 5 side and light incident from stage 6 side, and reflects the synthesized light to lens 2 side. Camera 1 images camera images A based on light incident via lens 2. Arithmetic equipment 8 obtains the position correction amount between first component P1 and second component P2 based on camera images A. Accordingly, since the position of first component P1 and the position of second component P2 can be recognized by one camera, it is possible to reduce the number of components constituting the optical system. Therefore, since it is possible to deter an occurrence of thermal expansion of the component constituting the optical system, it is possible to deter a decrease in positioning accuracy.

### Second Exemplary Embodiment

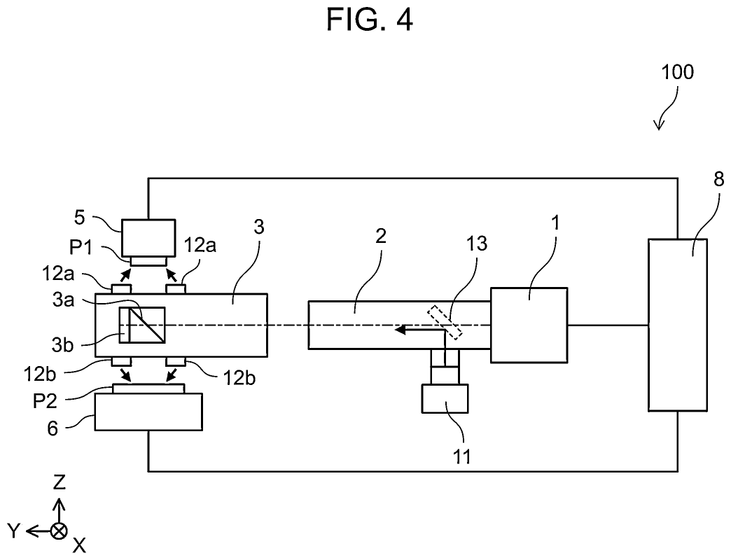

FIG. 4 illustrates a side view of a positioning equipment according to a second exemplary embodiment. The positioning equipment of FIG. 4 has a configuration substantially similar to the configuration of FIG. 1, but further includes coaxial illumination 11 and oblique light illuminations 12a, 12b (second illumination and third illumination).

Coaxial illumination 11 (first illumination or fourth illumination) irradiates light synthesis unit 3 with light in the Y direction via half mirror 13, and thus, first component P1 and second component P2 are irradiated with light from the Z direction. Oblique light illumination 12a (second illumination) irradiates first component P1 with light from an oblique direction (a direction inclined with respect to a direction from light synthesis unit 3 toward first component P1). Oblique light illumination 12b (third illumination) irradiates second component P2 with light from an oblique direction (a direction inclined with respect to a direction from light synthesis unit 3 toward second component P2).

In the second exemplary embodiment, marks M1, M2 given to first component P1 and second component P2, respectively, are more clearly displayed on camera images A for first component P1 and second component P2 by coaxial illumination 11 and oblique light illuminations 12a, 12b. Thus, the position correction amount between first component P1 and second component P2 can be obtained more accurately. Note that, positioning equipment 100 according to the present exemplary embodiment may include coaxial illumination 11 and may not include oblique light illuminations 12a, 12b. In addition, positioning equipment 100 according to the present exemplary embodiment may not include coaxial illumination 11 but may include oblique light illuminations 12a, 12b. In either configuration, marks M1, M2 given to first component P1 and second component P2, respectively, are displayed more clearly on camera images A for first component P1 and second component P2. Thus, the position correction amount between first component P1 and second component P2 can be obtained more accurately.

### Third Exemplary Embodiment

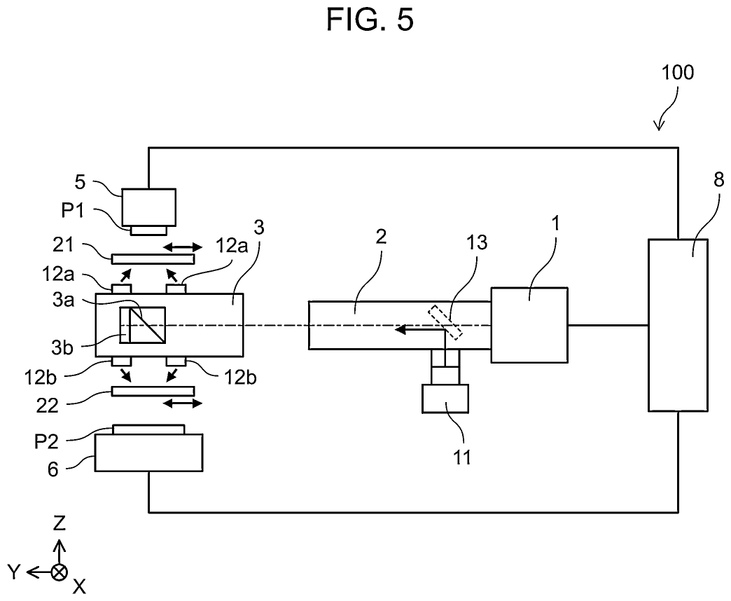

FIG. 5 illustrates a side view of a positioning equipment according to a third exemplary embodiment. The positioning equipment of FIG. 5 has a configuration substantially similar to the configuration of FIG. 4, but further includes mechanical shutters 21, 22.

Mechanical shutter 21 (first shielding unit or third shielding unit) is disposed between light synthesis unit 3 and bonding head 5. Mechanical shutter 22 (first shielding unit or fourth shielding unit) is disposed between light synthesis unit 3 and stage 6. Mechanical shutters 21, 22 are driven and opened and closed by a shutter drive unit (not illustrated). Specifically, when mechanical shutter 21 is closed, the incidence of light from bonding head 5 to light synthesis unit 3 (half mirror 3a) is shielded. In addition, when mechanical shutter 22 is closed, the incidence of light from stage 6 to light synthesis unit 3 (half mirror 3a) is shielded.

Next, an operation of the positioning equipment according to the third exemplary embodiment will be described. The positioning equipment of the third exemplary embodiment performs an operation similar to the flowchart of FIG. 2, but operations of steps S2, S3 are different.

In step S2, two camera images A are imaged. Specifically, in a state where mechanical shutter 21 is opened and mechanical shutter 22 is closed, camera 1 performs imaging, and images camera image A1 (first camera image, see part (b) of FIG. 3). Subsequently, in a state where mechanical shutter 21 is closed and mechanical shutter 22 is opened, camera 1 performs imaging, and images camera image A2 (second camera image, see part (c) of FIG. 3). At this time, first component P1 is imaged on camera image A1, and second component P2 is imaged on camera image A2.

Then, in step S3, the marks used for positioning are detected from camera images A1, A2, and the position correction amount between first component P1 and second component P2 is calculated.

In the third exemplary embodiment, first component P1 and second component P2 are imaged on different camera images A (camera images A1, A2) by opening and closing mechanical shutters 21, 22 (first shielding unit). Thus, an imaging condition is changed for each of camera images A1, A2, thus, it is possible to more clearly image marks M1, M2 given to first component P1 and second component P2, respectively. Therefore, the position correction amount between first component P1 and second component P2 can be obtained more accurately.

### Fourth Exemplary Embodiment

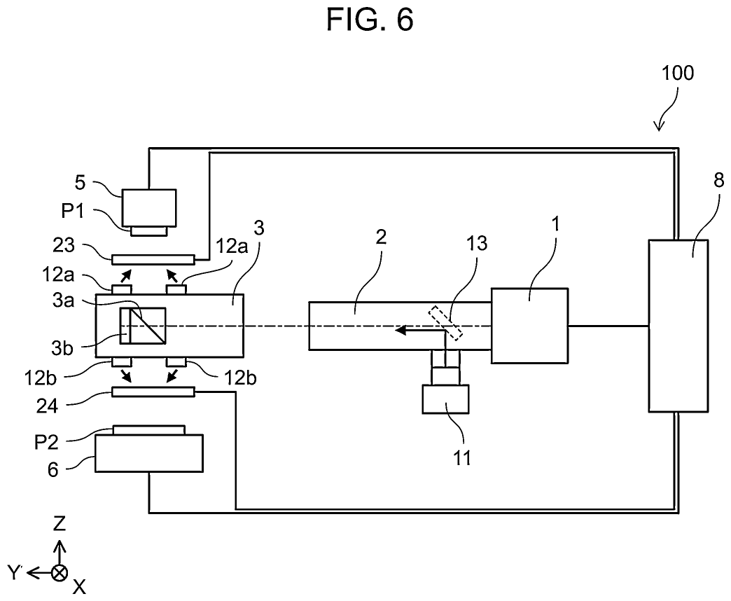

FIG. 6 illustrates a side view of a positioning equipment according to a fourth exemplary embodiment. The positioning equipment of FIG. 6 has a configuration substantially similar to the configuration of FIG. 4, but further includes electronic shutters 23, 24 (first shielding unit).

Electronic shutter 23 is disposed between light synthesis unit 3 and bonding head 5. Electronic shutter 24 is disposed between light synthesis unit 3 and stage 6. Each of electronic shutters 23, 24 includes, for example, a liquid crystal, a polarizing plate, or the like, and transmits or shields light in accordance with an electric signal input from arithmetic equipment 8. That is, electronic shutters 23, 24 are opened and closed according to an electric signal input from arithmetic equipment 8. Specifically, when electronic shutter 23 is closed, the incidence of light from bonding head 5 to light synthesis unit 3 (half mirror 3a) is shielded. In addition, when electronic shutter 24 is closed, the incidence of light from stage 6 to light synthesis unit 3 (half mirror 3a) is shielded.

Next, an operation of the positioning equipment according to the fourth exemplary embodiment will be described. The positioning equipment of the fourth exemplary embodiment performs an operation similar to the flowchart of FIG. 2, but operations of steps S2, S3 are different.

In step S2, two camera images A are imaged. Specifically, in a state where electronic shutter 23 is opened and electronic shutter 24 is closed, camera 1 performs imaging, and images camera image A1 (see part (b) of FIG. 3). Subsequently, in a state where electronic shutter 23 is closed and electronic shutter 24 is opened, camera 1 performs imaging, and images camera image A2 (see part (c) of FIG. 3). At this time, first component P1 is imaged on camera image A1, and second component P2 is imaged on camera image A2.

Then, in step S3, marks used for positioning are detected from camera images A1, A2, and the position correction amount between first component P1 and second component P2 is calculated.

In the fourth exemplary embodiment, first component P1 and second component P2 are imaged on different camera images A (camera images A1, A2) by opening and closing electronic shutters 23, 24 (first shielding unit). Thus, marks M1, M2 given to first component P1 and second component P2, respectively, can be more clearly imaged. Therefore, the position correction amount between first component P1 and second component P2 can be obtained more accurately.

In addition, since electronic shutters 23, 24 can be opened and closed without a physical operation, distortion, vibration, and the like of the positioning equipment due to the opening and closing of the shutters can be suppressed. Accordingly, more accurate positioning can be performed.

### Fifth Exemplary Embodiment

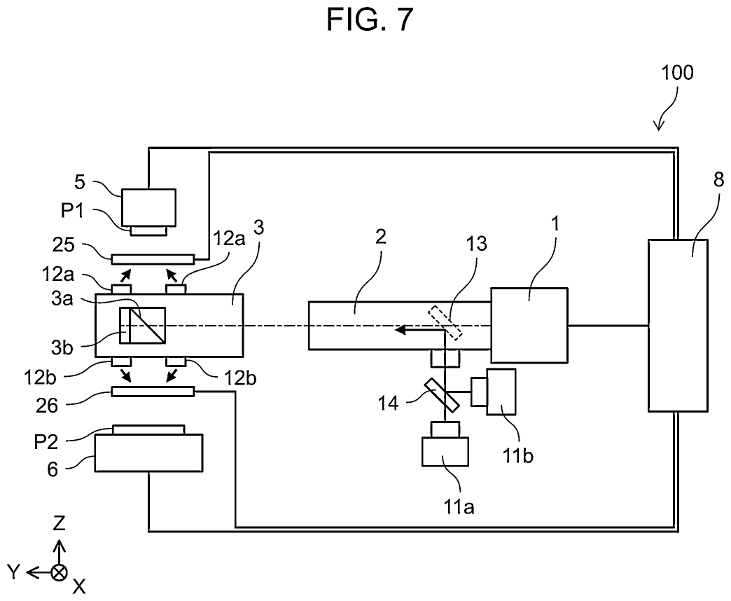

FIG. 7 illustrates a side view of a positioning equipment according to a fifth exemplary embodiment. The positioning equipment of FIG. 7 has a configuration substantially similar to the configuration of FIG. 4, but further includes color filters 25, 26. In addition, coaxial illuminations 11a, 11b are disposed instead of coaxial illumination 11.

Coaxial illumination 11a is an illumination that emits light in a first wavelength range. Coaxial illumination 11b is an illumination that emits light in a second wavelength range. The first wavelength range and the second wavelength range are wavelength ranges different from each other (bands not overlapping each other). For example, the first wavelength range is a red to near-infrared region of visible light, and the second wavelength range is a region near visible light blue on a short wavelength side. Note that, the first wavelength range and the second wavelength range may be set in any manner as long as there is no region overlapping each other.

In addition, coaxial illuminations 11a, 11b irradiate light synthesis unit 3 with light in the Y direction via half mirrors 13, 14. In addition, oblique light illumination 12a emits light in the first wavelength range, and oblique light illumination 12b emits light in the second wavelength range.

Color filter 25 (first color filter) is disposed between light synthesis unit 3 and bonding head 5. Color filter 26 (second color filter) is disposed between light synthesis unit 3 and stage 6. Color filters 25, 26 transmit the light in the first wavelength range and the light in the second wavelength range, respectively. That is, bonding head 5 (first component P1) is irradiated with the light in the first wavelength range, and stage 6 (second component P2) is irradiated with the light in the second wavelength range. Thus, on camera image A, an image of first component P1 is displayed based on the light in the first wavelength range, and an image of second component P2 is displayed based on the light in the second wavelength range.

In the fifth exemplary embodiment, the images of first component P1 and second component P2 are displayed on camera image A based on light rays in different wavelength ranges by color filters 25, 26 (first color filter and second color filter). Thus, marks M1, M2 given to first component P1 and second component P2, respectively, can be more clearly imaged. Therefore, the position correction amount between first component P1 and second component P2 can be obtained more accurately.

Note that, only one of coaxial illuminations 11a, 11b may emit light. That is, coaxial illuminations 11a, 11b can switch between first component P1 and second component P2, and can irradiate the first component and the second component with light in a band of the first wavelength range and light in a band of the second wavelength range. Accordingly, it is possible to generate the camera image on which first component P1 is imaged and the camera image on which second component P2 is imaged, and thus, it is possible to obtain the position correction amount between first component P1 and second component P2 by performing processing similar to the fourth exemplary embodiment and the like.

### Sixth Exemplary Embodiment

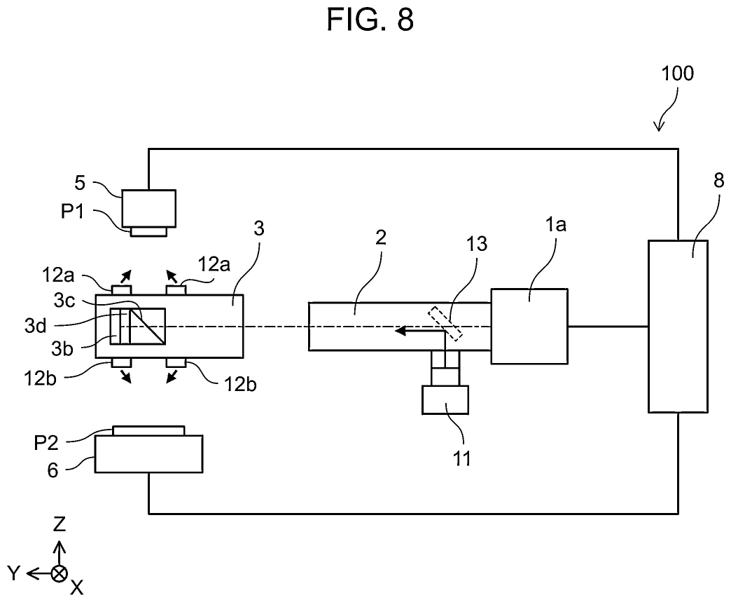

FIG. 8 illustrates a side view of a positioning equipment according to a sixth exemplary embodiment. The positioning equipment of FIG. 8 has a configuration substantially similar to the configuration of FIG. 4, but polarization camera 1a is disposed instead of camera 1. In addition, polarization beam splitter 3c is disposed instead of half mirror 3a. In addition, a ¼ wave plate 3d is disposed between polarization beam splitter 3c and mirror 3b.

Polarization beam splitter 3c is an optical element that transmits S-polarized light (first polarized light) and reflects P-polarized light (second polarized light) among the incident light rays. ¼ wave plate 3d is an optical element that causes a phase difference of N/4 between orthogonal polarized components in the incident light. That is, ¼ wave plate 3d changes a polarization direction of the transmitted light.

Polarization camera 1a is a camera that generates a camera image in accordance with a polarization direction of the incident light. In the present exemplary embodiment, polarization camera 1a generates one camera image based on the S-polarized light, and generates one camera image based on the P-polarized light.

In the sixth exemplary embodiment, among the light rays emitted from coaxial illumination 11 to polarization beam splitter 3c, S-polarized light (hereinafter, referred to as “first light”) is reflected by polarization beam splitter 3c and are emitted to bonding head 5. Then, third light that is a part of the first light is reflected by the surface of first component P1, is further reflected by polarization beam splitter 3c, and is incident on polarization camera 1a.

In addition, among irradiation light rays emitted from coaxial illumination 11 to polarization beam splitter 3c, P-polarized light (hereinafter, referred to as “second light”) is transmitted through polarization beam splitter 3c and is incident on mirror 3b. At this time, since the second light is transmitted through ¼ wave plate 3d, the second light is changed from the P-polarized light to circularly polarized light. Thereafter, the second light is reflected by mirror 3b, and is incident on polarization beam splitter 3c. At this time, since the second light is transmitted through ¼ wave plate 3d again, the circularly polarized light is changed to the S-polarized light. Thus, the second light is reflected by polarization beam splitter 3c, and is applied to stage 6. Then, fourth light that is a part of the second light is reflected by the surface of first component P2, is further reflected by polarization beam splitter 3c, and is incident on mirror 3b. At this time, since the fourth light is transmitted through ¼ wave plate 3d, the fourth light is changed from the S-polarized light to the circularly polarized light. Thereafter, the fourth light is reflected by mirror 3b, and is incident on polarization beam splitter 3c. At this time, since the fourth light is transmitted through ¼ wave plate 3d again, the fourth light is changed from the circularly polarized light to the P-polarized light. Thus, the fourth light is transmitted through polarization beam splitter 3c, and is incident on camera 1.

That is, the image of first component P1 is generated by the S-polarized light (third light) among the irradiation light rays of coaxial illumination 11, and the image of second component P2 is generated by the P-polarized light (fourth light) among the irradiation light rays of coaxial illumination 11. Thus, polarization camera 1a images (generates) camera image A for each of first component P1 and second component P2.

In the sixth exemplary embodiment, the images of first component P1 and second component P2 are displayed on camera image A by polarization beam splitter 3c and ¼ wave plate 3d based on light rays in different polarization directions. Thus, marks M1, M2 given to first component P1 and second component P2, respectively, can be more clearly imaged. Therefore, the position correction amount between first component P1 and second component P2 can be obtained more accurately.

### Seventh Exemplary Embodiment

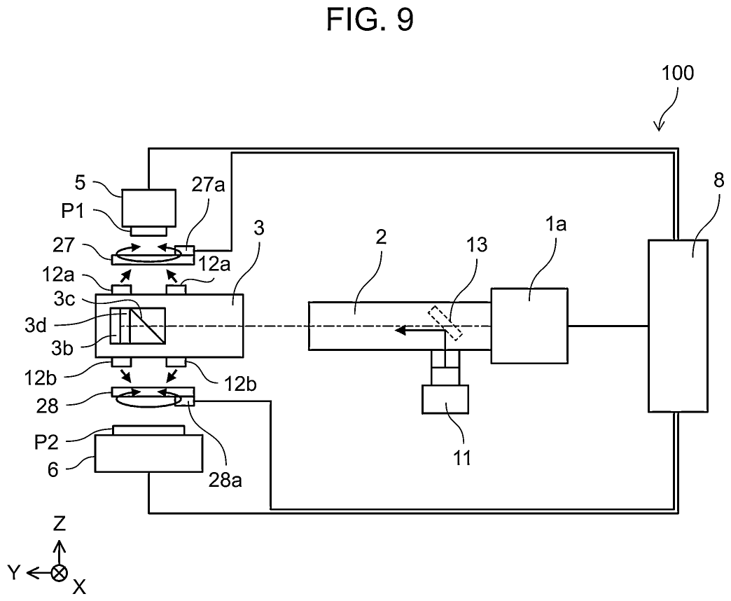

FIG. 9 illustrates a side view of a positioning equipment according to a seventh exemplary embodiment. The positioning equipment of FIG. 9 has a configuration substantially similar to the configuration of FIG. 8, but further includes polarizing plates 27, 28.

Polarizing plate 27 (first polarizing plate or third polarizing plate) is disposed between light synthesis unit 3 and bonding head 5. Polarizing plate 28 (first polarizing plate or third polarizing plate) is disposed between light synthesis unit 3 and stage 6. Polarizing plates 27 and 28 are optical elements that transmit light in a predetermined polarization direction. In addition, orientations of polarizing plates 27 and 28 are changed by drive units 27a and 28a (first drive unit). That is, in polarizing plates 27 and 28, the polarization direction of the transmitted light is changed by drive units 27a, 28a.

Next, an operation of the positioning equipment according to the seventh exemplary embodiment will be described. The positioning equipment of the seventh exemplary embodiment performs an operation similar to the flowchart of FIG. 2, but operations of steps S2, S3 are different.

In step S2, two camera images A are imaged. Specifically, in a state where orientations of polarizing plate 27 and polarizing plate 28 are changed such that polarizing plate 27 transmits the first light and polarizing plate 28 does not to transmit the second light, camera 1 performs imaging, and images camera image A1 (third camera image, see part (b) of FIG. 3). Subsequently, in a state where orientations of polarizing plate 27 and polarizing plate 28 are changed such that polarizing plate 27 does not transmit the first light and polarizing plate 28 transmits the second light, camera 1 performs imaging, and images camera image A2 (fourth camera image, see part (c) of FIG. 3). Note that, as described above, the first light and the second light are the S-polarized light rays when the light rays are transmitted through polarizing plates 27, 28, respectively.

Then, in step S3, marks used for positioning are detected from camera images A1, A2, and the position correction amount between first component P1 and second component P2 is calculated.

In the seventh exemplary embodiment, first component P1 and second component P2 are imaged on different camera images A (camera images A1, A2) by changing the orientations of polarizing plates 27, 28 (first polarizing plates). Thus, marks M1, M2 given to first component P1 and second component P2, respectively, can be more clearly imaged. Therefore, the position correction amount between first component P1 and second component P2 can be obtained more accurately.

In addition, since center-of-gravity movement amounts of polarizing plates 27, 28 are small, distortion or the like of the positioning equipment due to the change in the orientations of polarizing plates 27, 28 can be suppressed. Accordingly, more accurate positioning can be performed.

Note that, in FIG. 9, a polarizing element that changes the polarization direction of the transmitted light in accordance with an electric signal may be disposed instead of polarizing plates 27, 28.

### Eighth Exemplary Embodiment

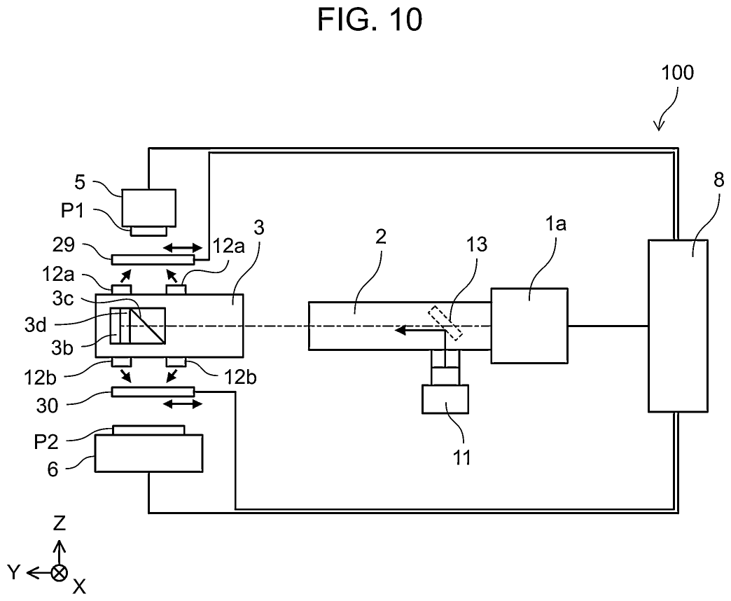

FIG. 10 illustrates a side view of a positioning equipment according to an eighth exemplary embodiment. The positioning equipment of FIG. 10 has a configuration substantially similar to the configuration of FIG. 8, but further includes electronic shutters 29, 30 (second shielding unit).

Electronic shutter 29 is disposed between light synthesis unit 3 and bonding head 5. Electronic shutter 30 is disposed between light synthesis unit 3 and stage 6. Each of electronic shutters 29, 30 includes, for example, a liquid crystal, a polarizing plate, or the like, and transmits or shields light in accordance with an electric signal from arithmetic equipment 8. That is, electronic shutters 29, 30 are opened and closed according to a predetermined signal. Specifically, when electronic shutter 29 is closed, the incidence of light from bonding head 5 to light synthesis unit 3 (half mirror 3a) is shielded. In addition, when electronic shutter 30 is closed, the incidence of light from stage 6 to light synthesis unit 3 (half mirror 3a) is shielded.

When the liquid crystal is used for electronic shutter 29, a set of a polarizing plate and a liquid crystal for switching the polarization direction may be used, and the shutter (transmission and shielding) may be performed by a combination of polarization beam splitter 3c and the polarization direction. For example, after light from the workpiece side is changed to the S-polarized light by using the polarizing plate, in a case where the polarization direction is not changed by the liquid crystal (electronic shutter 29), the light is changed to the S-polarized light as it is, and can be imaged by being reflected by polarization beam splitter 3c. On the other hand, when the light from the workpiece side is changed to the S-polarized light by using the polarizing plate and then the polarization direction is changed by changing a voltage applied to the liquid crystal, the light passing through the liquid crystal can be changed to the P-polarized light. In this case, since the light is transmitted through polarization beam splitter 3c, imaging cannot be performed. It is also possible to electrically select whether or not imaging is performed based on such a principle.

Next, an operation of the positioning equipment according to the eighth exemplary embodiment will be described. The positioning equipment of the eighth exemplary embodiment performs an operation similar to the flowchart of FIG. 2, but operations of steps S2, S3 are different.

In step S2, two camera images A are imaged. Specifically, in a state where electronic shutter 29 is opened and electronic shutter 30 is closed, camera 1 performs imaging, and images camera image A1 (see (b) of FIG. 3). Subsequently, in a state where electronic shutter 29 is closed and electronic shutter 30 is opened, camera 1 performs imaging, and images camera image A2 (see (c) of FIG. 3). At this time, first component P1 is imaged on camera image A1, and second component P2 is imaged on camera image A2.

Then, in step S3, the marks used for positioning are detected from camera images A1, A2, and the position correction amount between first component P1 and second component P2 is calculated.

In the eighth exemplary embodiment, first component P1 and second component P2 are imaged on different camera images A (camera images A1, A2) by opening and closing electronic shutters 29, 30 (second shielding unit). Thus, marks M1, M2 given to first component P1 and second component P2, respectively, can be more clearly imaged. Therefore, the position correction amount between first component P1 and second component P2 can be obtained more accurately.

In addition, since electronic shutters 29, 30 can be opened and closed without a physical operation, distortion or the like of the positioning equipment due to the opening and closing of the shutters can be suppressed. Accordingly, more accurate positioning can be performed.

### Ninth Exemplary Embodiment

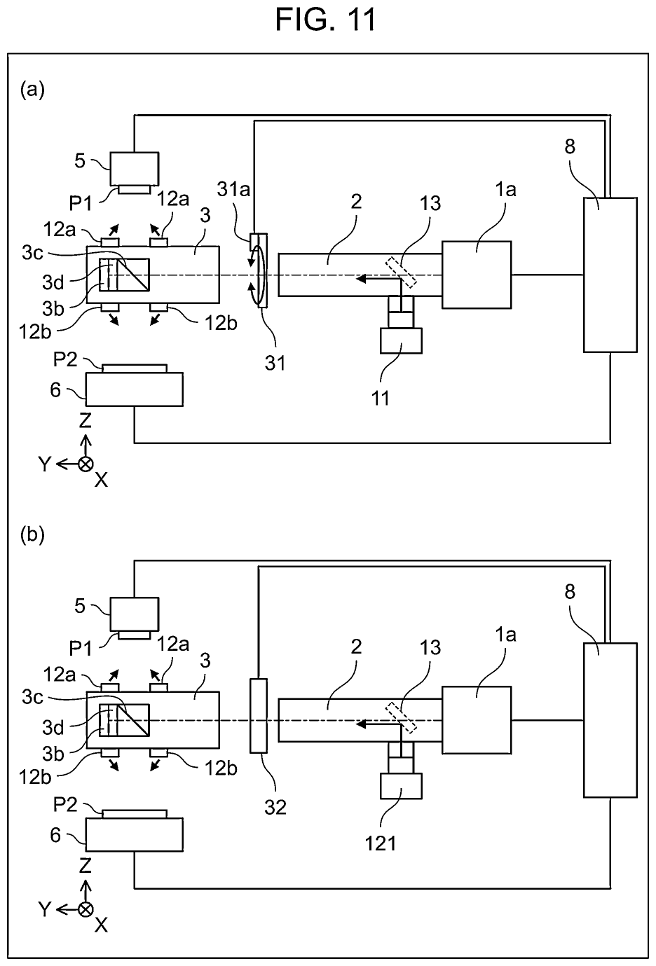

Part (a) of FIG. 11 illustrates a side view of a positioning equipment according to a ninth exemplary embodiment. The positioning equipment of part (a) of FIG. 11 has a configuration substantially similar to the configuration of FIG. 8, but further includes polarizing plate 31.

Polarizing plate 31 (second polarizing plate) is disposed between lens 2 and light synthesis unit 3. Polarizing plate 31 is an optical element that transmits light in a predetermined polarization direction. In addition, an orientation of polarizing plate 31 is changed by drive unit 31a (second drive unit). That is, in polarizing plate 31, the polarization direction of the transmitted light is changed by drive unit 31a.

Next, an operation of the positioning equipment according to the ninth exemplary embodiment will be described. The positioning equipment of the tenth exemplary embodiment performs an operation similar to the flowchart of FIG. 2, but operations of steps S2, S3 are different.

In step S2, two camera images A are imaged. Specifically, in a state where an orientation of polarizing plate 31 is changed such that polarizing plate 31 transmits the S-polarized light and shields the P-polarized light, camera 1 performs imaging, and images camera image A1 (fifth camera image, see part (b) of FIG. 3). At this time, since the S-polarized light is transmitted through polarizing plate 31, first component P1 is imaged on camera image A1. Subsequently, in a state where the orientation of polarizing plate 31 is changed such that polarizing plate 31 shields the S-polarized light and transmits the P-polarized light, camera 1 performs imaging, and images camera image A2 (fifth camera image, see part (c) of FIG. 3). At this time, since polarizing plate 31 transmits the P-polarized light, second component P2 is imaged on camera image A2.

Then, in step S3, the marks used for positioning are detected from camera images A1, A2, and the position correction amount between first component P1 and second component P2 is calculated.

In the ninth exemplary embodiment, first component P1 and second component P2 are imaged on different camera images A (camera images A1, A2) by changing the orientation of polarizing plate 31. Thus, marks M1, M2 given to first component P1 and second component P2, respectively, can be more clearly imaged. Therefore, the position correction amount between first component P1 and second component P2 can be obtained more accurately.

Part (b) of FIG. 11 illustrates a side view of another example of the positioning equipment according to the ninth exemplary embodiment. Part (b) of FIG. 11 has a configuration substantially similar to the configuration of part (a) of FIG. 11, but polarizing element 32 that changes the polarization direction of the transmitted light in accordance with the electric signal is disposed instead of polarizing plate 31. Even with this configuration, effects similar to the effects part (a) of FIG. 11 can be obtained.

Note that, in the first to fifth exemplary embodiments, half mirror 3a reflects the light incident from bonding head 5 in the optical axis direction of lens 2 and reflects the light incident from stage 6 to mirror 3b, but the present invention is not limited thereto. For example, half mirror 3a may reflect the light incident from bonding head 5 to mirror 3b, and may reflect the light incident from stage 6 in the optical axis direction of lens 2.

In addition, in the sixth to ninth exemplary embodiments, polarization beam splitter 3c transmits the S-polarized light and reflects the P-polarized light among the incident light rays, but the present invention is not limited thereto. For example, polarization beam splitter 3c may transmit the P-polarized light and may reflect the S-polarized light among the incident light rays. That is, the light transmitted through polarization beam splitter 3c may be applied to first component P1, and the light reflected by polarization beam splitter 3c may be applied to second component P2. Note that, polarization beam splitter 3c may reflect the S-polarized light and may transmit the P-polarized light.

### INDUSTRIAL APPLICABILITY

The positioning equipment of the present disclosure can be used when positioning is performed at the time of manufacturing an electronic component or the like.

### REFERENCE MARKS IN THE DRAWINGS

1: camera
1a: polarization camera
2: lens
3: light synthesis unit (optical element)
3a: half mirror
3c: polarization beam splitter
3d: ¼ wave plate
5: bonding head
6: stage
8: arithmetic equipment
11: coaxial illumination (first illumination or fourth illumination)
12a: oblique light illumination (second illumination)
12b: oblique light illumination (third illumination)
21, 22: mechanical shutter (first shielding unit)
23: electronic shutter (first shielding unit or third shielding unit)
24: electronic shutter (first shielding unit or fourth shielding unit)
25: color filter (first color filter)
26: color filter (second color filter)
27: polarizing plate (first polarizing plate or third polarizing plate)
28: polarizing plate (first polarizing plate or fourth polarizing plate)
27a, 28a: drive unit (first drive unit)
29,30: electronic shutter (second shielding unit)
31: polarizing plate (second polarizing plate)
31a: drive unit (second drive unit)
32: polarizing element
A: camera image
A1: camera image (first camera image, third camera image, or fifth camera image)
A2: camera image (second camera image, fourth camera image, or sixth camera image)
M1, M2: mark
P1: first component
P2: second component

1. A positioning equipment that positions a first component retained by a bonding head and a second component placed on a stage when the first component is mounted on the second component, the positioning equipment comprising:
a camera;
a lens disposed in an imaging direction of the camera;
an optical element; and
an arithmetic equipment,
wherein
the optical element is disposed between the bonding head and the stage when the first component and the second component are positioned, synthesizes light incident from the bonding head side and light incident from the stage side, and reflects the synthesized light to the lens side,
the camera images a camera image based on light incident via the lens, and
the arithmetic equipment obtains a position correction amount between the first component and the second component based on the camera image.

2. The positioning equipment according to claim 1, further comprising a first illumination that irradiates at least one of the first component and the second component with light via the optical element by emitting light along the imaging direction of the camera.

3. The positioning equipment according to claim 1, wherein
the optical element includes a half mirror and a mirror,
the half mirror reflects light incident from one side of the bonding head side and the stage side to the lens side, and reflects light incident from the other side of the bonding head side and the stage side to the mirror side, and
the mirror reflects light incident from the half mirror to the lens side.

4. The positioning equipment according to claim 1, further comprising a first shielding unit that shields the light between the optical element and at least one of the bonding head and the stage.

5. The positioning equipment according to claim 4, wherein the first shielding unit is a mechanical shutter.

6. The positioning equipment according to claim 4, wherein the first shielding unit is an electronic shutter opened and closed according to an input electric signal.

7. The positioning equipment according to claim 1, further comprising:
a first color filter disposed between the bonding head and the optical element to transmit light in a first wavelength range;
a second color filter disposed between the stage and the optical element to transmit light in a second wavelength range that is a band not overlapping with the first wavelength range; and
a third illumination configured to switch between the first component and the second component and to irradiate the first component and the second component with light in a band within the first wavelength range and light in a band within the second wavelength range.

8. The positioning equipment according to claim 1, further comprising a fourth illumination that irradiates the optical element with light along the imaging direction of the camera, wherein
the optical element includes
a polarization beam splitter that receives light from the fourth illumination, reflects first polarized light and transmits second polarized light, among incident light rays,
a mirror that reflects incident light rays, and
a wave plate that is disposed between the polarization beam splitter and the mirror to change a polarization direction of transmitted light,
the polarization beam splitter reflects first light that is the first polarized light, among the incident light rays, to one side of the bonding head side and the stage side, and transmits second light that is the second polarized light,
the wave plate changes the second light transmitted through the polarization beam splitter from the second polarized light to circularly polarized light, and causes the circularly polarized light to be incident on the mirror,
the mirror reflects the second light to the wave plate side, and
the wave plate changes the second light from the circularly polarized light to the first polarized light, and causes the first polarized light to be incident on the polarization beam splitter, and
the polarization beam splitter reflects the second light to the other side of the bonding head side and the stage side.

9. The positioning equipment according to claim 8, wherein
the camera is a polarization camera that images the camera image based on each of third light that is a part of the first light and fourth light that is a part of the second light,
the third light is incident on the camera by being reflected by the first component and then being reflected by the polarization beam splitter to the camera side, and
the fourth light is incident on the camera by being reflected by the second component, being reflected to the mirror side by the polarization beam splitter, being changed from the first polarized light to the circularly polarized light by the wave plate, then being reflected to the polarization beam splitter side by the mirror, being changed from the circularly polarized light to the second polarized light by the wave plate, and being transmitted through the polarization beam splitter.

10. The positioning equipment according to claim 8, further comprising:
a first polarizing plate disposed between the optical element and at least one of the bonding head and the stage; and
a first drive unit that changes a polarization direction of light transmitted through the first polarizing plate by changing an orientation of the first polarizing plate.

11. The positioning equipment according to claim 8, further comprising a second shielding unit that shields the light between the optical element and at least one of the bonding head and the stage.

12. The positioning equipment according to claim 8, further comprising:
a second polarizing plate disposed between the polarization beam splitter and the lens; and
a second drive unit that changes a polarization direction of light transmitted through the second polarizing plate by changing an orientation of the second polarizing plate.

13. The positioning equipment according to claim 8, further comprising a polarizing element between the polarization beam splitter and the lens, the polarizing element being configured to change a polarization direction of transmitted light by and an electrical unit.

14. The positioning equipment according to claim 1, further comprising:
a second illumination that irradiates the first component with light from a direction inclined with respect to a direction from the optical element toward the first component; and
a third illumination that irradiates the second component with light from a direction inclined with respect to a direction from the optical element toward the second component.

15. A bonding equipment comprising:
the positioning equipment according to claim 1;
the bonding head;
the stage; and
a moving mechanism that moves at least one of the bonding head and the stage.

16. A positioning method using the positioning equipment according to claim 4, the first shielding unit including a third shielding unit disposed between the optical element and the bonding head, and a fourth shielding unit disposed between the optical element and the stage, the method comprising:
imaging, by the camera, a first camera image that is the camera image in a state where light incident on the optical element from the bonding head is shielded by the third shielding unit;
imaging, by the camera, a second camera image that is the camera image in a state where light incident on the optical element from the stage is shielded by the fourth shielding unit; and
obtaining, by the arithmetic equipment, a position correction amount between the first component and the second component based on the first camera image and the second camera image.

17. A positioning method using the positioning equipment according to claim 10, the first polarizing plate including a third polarizing plate disposed between the optical element and the bonding head and a fourth polarizing plate disposed between the optical element and the stage, the method comprising:
imaging, by the camera, a third camera image that is the camera image in a state where orientations of the third polarizing plate and the fourth polarizing plate are changed by the first drive unit, the third polarizing plate transmitting the first light and the fourth polarizing plate shielding the second light;
imaging, by the camera, a fourth camera image that is the camera image in a state where the orientations of the third polarizing plate and the fourth polarizing plate are changed by the first drive unit, the third polarizing plate shielding the first light and the fourth polarizing plate transmitting the second light; and
obtaining, by the arithmetic equipment, a position correction amount between the first component and the second component based on the third camera image and the fourth camera image.

18. A positioning method using the positioning equipment according to claim 12, the method comprising:
imaging, by the camera, a fifth camera image that is the camera image in a state where an orientation of the second polarizing plate is changed by the second drive unit, the second polarizing plate transmitting the first polarized light and shielding the second polarized light, among the light rays incident from the fourth illumination; and
imaging, by the camera, a sixth camera image that is the camera image in a state where the orientation of the second polarizing plate is changed by the second drive unit, the second polarizing plate shielding the first polarized light and transmitting the second polarized light, among the light rays incident from the fourth illumination; and
obtaining, by the arithmetic equipment, a position correction amount between the first component and the second component based on the fifth camera image and the sixth camera image.

19. A bonding method comprising:
the positioning method according to claim 16; and
bonding the first component on the second component.
